(19) United States
(12) Patent Application Publication
(10) Pub. No.: US 2024/0410057 A1
(43) Pub. Date: Dec. 12, 2024

(54) SUBSTRATE PROCESSING METHOD AND SUBSTRATE PROCESSING APPARATUS

(71) Applicants: SEMES CO., LTD., Cheonan-si (KR); Research & Business Foundation SUNGKYUNKWAN UNIVERSITY, Suwon-si (KR)

(72) Inventors: Sung Min CHOI, Cheonan-si (KR); Heeyeop CHAE, Seoul (KR); Hojin KANG, Suwon-si (KR); Hyeongwu LEE, Suwon-si (KR); Heeju HA, Suwon-si (KR)

(73) Assignees: SEMES CO., LTD., Cheonan-si (KR); Research & Business Foundation SUNGKYUNKWAN UNIVERSITY, Cheonan-si (KR)

(21) Appl. No.: 18/615,556

(22) Filed: Mar. 25, 2024

(30) Foreign Application Priority Data
Jun. 9, 2023 (KR) 10-2023-0074478

(51) Int. Cl. C23F 1/14; C23F 1/08

(52) U.S. Cl. CPC C23F 1/14; C23F 1/08

(57) ABSTRACT

Proposed are a substrate processing method and a substrate processing apparatus. A substrate processing method according to an embodiment is for etching a thin film formed on a substrate at the atomic layer level, and includes a surface modification step of modifying a surface of the thin film by supplying a first gas including chlorine (Cl) to a processing space of a chamber in which the substrate is placed, a first purge step of removing the first gas remaining in the processing space by supplying a purge gas to the processing space, an etching step of etching the modified thin film by supplying a second gas including acetylacetone (Hacac) to the processing space, and a second purge step of removing the second gas remaining in the processing space by supplying the purge gas to the processing space.

### CROSS-REFERENCE TO RELATED APPLICATION(S)

This application claims priority under 35 U.S.C. § 119 to Korean Patent Application No. 10-2023-0074478, filed on Jun. 9, 2023 in the Korean Intellectual Property Office, the disclosure of which is incorporated by reference herein in its entirety.

### BACKGROUND OF THE INVENTION

### Field of the Invention

The present disclosure relates generally to a substrate processing method and a substrate processing apparatus. More particularly, the present disclosure relates to a substrate processing method and a substrate processing apparatus for etching a cobalt film at the atomic layer level.

### Description of the Related Art

With the increase in use of smartphones, tablet PCs, and solid state drives (SSDs), the demand for memory devices has increased rapidly. In particular, the need for low-power, highly integrated, and high-capacity flash memory is increasing.

In the case of conventional 2D structured flash memory, as the line width of cells decreases, interference between cells intensifies and leakage current occurs. As a solution to these problems, a 3D NAND flash structure in which cells are stacked vertically in three dimensions is gaining attention. This vertical stack structure allows more cells to be implemented in the same silicon area, which has the advantage of lowering manufacturing costs and increasing capacity.

The conventional 3D NAND flash has a structure formed by alternately stacking silicon oxide films and silicon nitride films and etching the stacked films to form source lines and word lines. FIG. 1 is a view partially illustrating the process of manufacturing 3D NAND flash. Referring to FIG. 1, 3D NAND flash can be manufactured by depositing various materials such as a tunneling oxide, a nitride film trap, a gate insulating layer, a barrier layer, and a gate in word lines, and then etching them to the formed nitride film trap. The recent trend of 3D NAND flash technology is increasing the number of layers to increase the capacity and making the pattern finer. Thus, in the 3D NAND flash manufacturing process, an importance of the etching process is increasingly recognized.

Among the above-described configurations, the gate allows current to flow through a device according to voltage applied to the gate, and is mainly made of a metal material. A common example of the material constituting the gate is cobalt. Generally, the gate is formed by depositing a cobalt film in openings where a gate insulating layer and a barrier layer are formed, and then etching the deposited cobalt film through an etching process to make the film uniform.

Conventionally, the etching of the cobalt film is achieved using an atomic layer etching (ALE) process. In this regard, Non-patent Document 1 discloses a method of modifying a cobalt film using chlorine (Cl) gas and etching the modified cobalt film at the atomic layer level using hexafluoroacetylacetone (Hhfac). Since the Hfac presented in Non-Patent Document 1 is a very costly material, the use thereof in manufacturing 3D NAND flash has the problem of high device manufacturing cost.

The foregoing is intended merely to aid in the understanding of the background of the present disclosure, and is not intended to mean that the present disclosure falls within the purview of the related art that is already known to those skilled in the art. Documents of Related Art

(Non-Patent document 1) Mahsa Konh, Molecular mechanisms of atomic layer etching of cobalt with sequential exposure to molecular chlorine and diketones, Journal of Vacuum Science Technology A, 2019, 37(2), pages 021004-1-021004-8

### SUMMARY OF THE INVENTION

Accordingly, the present disclosure has been made keeping in mind the above problems occurring in the related art, and an objective of the present disclosure is to provide a substrate processing method and a substrate processing apparatus for reducing the manufacturing cost of devices.

The objectives of the present disclosure are not limited to those mentioned above, and other objectives not mentioned will be clearly understood by those skilled in the art from the following description.

In order to achieve the above objective, according to one aspect of the present disclosure, there is provided a substrate processing method for etching a thin film formed on a substrate at an atomic layer level, the substrate processing method including: a surface modification step of modifying a surface of the thin film by supplying a first gas including chlorine (Cl) to a processing space of a chamber in which the substrate is placed; a first purge step of removing the first gas remaining in the processing space by supplying a purge gas to the processing space; an etching step of etching the modified thin film by supplying a second gas including acetylacetone (Hacac) to the processing space; and a second purge step of removing the second gas remaining in the processing space by supplying the purge gas to the processing space.

In one embodiment, a cycle including the surface modification step to the second purge step may be repeated at least 1 time.

In one embodiment, the thin film may be a cobalt film.

In one embodiment, the substrate may include at least one of a silicon oxide film and a silicon nitride film.

In one embodiment, the substrate may include a stacked film in which the silicon oxide film and the silicon nitride film are alternately stacked, and the cobalt film may be formed in an opening formed through the stacked film.

In one embodiment, the first gas may be Cl₂, and the second gas may be a mixed gas of the Hacac and nitrogen (N₂).

In one embodiment, the surface modification step may be performed in a state in which a plasma of the first gas is generated in the processing space.

In one embodiment, the surface modification step to the second purge step may be performed in a state in which the substrate is heated to a predetermined temperature.

In one embodiment, the predetermined temperature may be 125° C. to 175° C.

According to another aspect of the present disclosure, there is provided a substrate processing apparatus, including: a chamber having a processing space therein; a substrate support unit disposed in the processing space, configured to support a substrate, and including a heating member configured to heat the substrate; a gas supply unit configured to supply a first gas including chlorine (Cl) and a second gas including acetylacetone (Hacac) to the processing space; a plasma generation unit configured to convert the gases supplied from the gas supply unit into a plasma state; and a control unit configured to control the gas supply unit and the plasma generation unit. The control unit may control the gas supply unit and the plasma generation unit so that a plasma of the first gas is generated in the processing space to modify a thin film formed on the substrate and the second gas is supplied to the processing space to etch the modified thin film formed on the substrate.

In one embodiment, the thin film may be a cobalt film.

In one embodiment, the cobalt film may be formed on a silicon oxide or silicon nitride film.

In one embodiment, the first gas may be Cl₂, and the second gas may be a mixed gas of the Hacac and nitrogen (N₂).

In one embodiment, the control unit may control the heating member to maintain a temperature of the substrate at 125° C. to 175° C.

According to another aspect of the present disclosure, there is provided a substrate processing method for etching a thin film formed on a substrate for manufacturing 3D NAND devices at an atomic layer level, the substrate processing method including: a surface modification step of modifying a surface of the thin film by supplying a first gas including chlorine (Cl) to a processing space of a chamber; a first purge step of removing the first gas remaining in the processing space by supplying a purge gas to the processing space; an etching step of etching the modified thin film by supplying a second gas including acetylacetone (Hacac) to the processing space; and a second purge step of removing the second gas remaining in the processing space by supplying the purge gas to the processing space. The first gas may be Cl₂, the second gas may be a mixed gas of the Hacac and nitrogen (N₂), and one cycle defined from the surface modification step to the second purge step may be repeated at least 1 time and may performed while maintaining the substrate at a temperature of 125° C. to 175° C.

In one embodiment, the thin film may be a cobalt film.

In one embodiment, the substrate may include at least one of a silicon oxide film and a silicon nitride film.

In one embodiment, the substrate may include a stacked film in which the silicon oxide film and the silicon nitride film are alternately stacked vertically, and the cobalt film may be formed in an opening formed through the stacked film.

In one embodiment, the substrate may include: a stacked film in which the silicon oxide film and the silicon nitride film are alternately stacked vertically; a slit-shaped first opening formed by etching the stacked film vertically; and a plurality of second openings formed to extend horizontally from the first opening by selectively etching the silicon nitride film exposed in the first opening. The cobalt film may be formed on surfaces of the first opening and the second openings.

In one embodiment, a tunneling oxide may be formed along the surfaces of the first opening and the second openings, a nitride film trap may be formed on the tunneling oxide, a gate insulating film may be formed on the nitride film trap, a barrier layer may be formed on the gate insulating film, and the cobalt film may be formed on the barrier layer.

According to the present disclosure, by modifying a thin film, that is, a cobalt film, formed on a substrate with a first gas including chlorine (Cl) and etching the modified cobalt film with a second gas including Hacac at the atomic layer level, it is possible to reduce the manufacturing cost of devices.

In addition, by etching the cobalt film at the atomic layer level using these gases, it is possible to reduce the surface roughness of the etched cobalt film, thereby reducing device defects.

The effects of the present disclosure are not limited to those mentioned above, and other effects not mentioned will be clearly understood by those skilled in the art from the following description.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view partially illustrating the process of manufacturing 3D NAND flash;

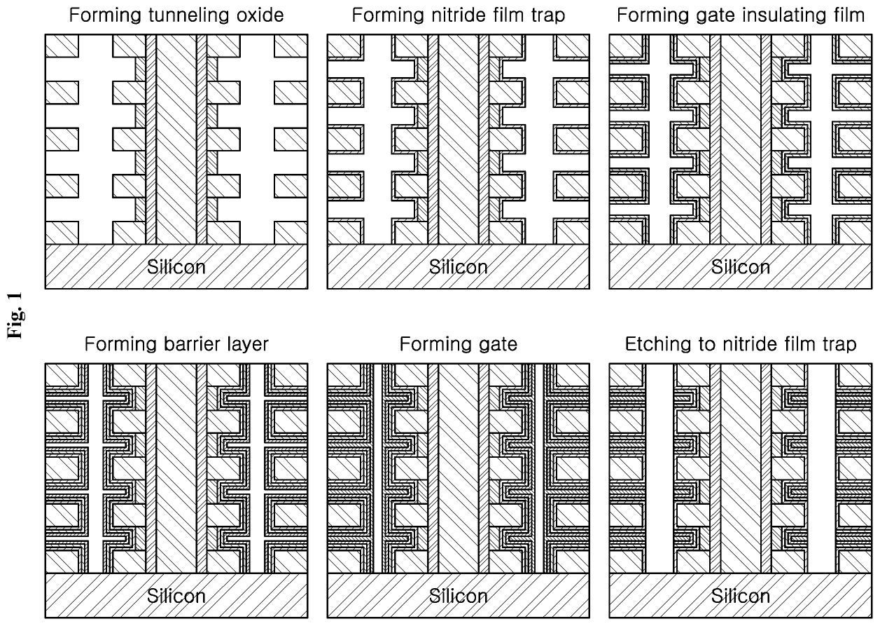

FIG. 2 is a flowchart illustrating a substrate processing method according to an embodiment of the present disclosure;

FIG. 3 is a schematic sectional view illustrating a substrate processing apparatus according to an embodiment of the present disclosure;

FIG. 4 is a graph illustrating the etch rate according to the temperature of a substrate according to an embodiment of the present disclosure;

FIG. 5 is a graph illustrating the surface roughness of an etched substrate according to the embodiment of the present disclosure; and

FIG. 6 is a graph illustrating the etching selectivity according to the type of substrate according to the embodiment of the present disclosure.

### DETAILED DESCRIPTION OF THE INVENTION

The present disclosure will now be described in detail with reference to the accompanying drawings so that those skilled in the art may easily practice the present disclosure. The present disclosure may, however, be embodied in many different forms and should not be construed as being limited to only the embodiments set forth herein.

In the following description, it is to be noted that, when the functions of conventional elements and the detailed description of elements related with the present disclosure may make the gist of the present disclosure unclear, a detailed description of those elements will be omitted. Wherever possible, the same reference numerals will be used throughout the drawings and the description to refer to the same or like elements or parts.

Technical terms, as will be mentioned hereinafter, are terms defined in consideration of their function in the present disclosure, which may be varied according to the intention of a user, practice, or the like. Thus, the terms should be defined on the basis of the contents of this specification.

As used herein, the singular forms are intended to include the plural forms as well, unless the context clearly indicates otherwise. It will be further understood that the terms “comprising” and/or “including” when used herein, specify the presence of stated features, integers, steps, operations, elements, and/or components, but do not preclude the presence or addition of one or more other features, integers, steps, operations, elements, components, and/or groups thereof.

In the figures, the size or shape of elements or the thickness of lines may be exaggerated for clarity of illustration.

Hereinafter, exemplary embodiments of the present disclosure will be described in detail with reference to the accompanying drawings, in which identical or similar constituent elements are given the same reference numerals regardless of the reference numerals of the drawings, and repeated description thereof will be omitted.

A substrate according to the embodiment of the present disclosure is a silicon substrate on which a silicon oxide film or silicon nitride film is formed, and a thin film may be formed on the silicon oxide film or silicon nitride film. The thin film may be a cobalt film, but is not limited thereto.

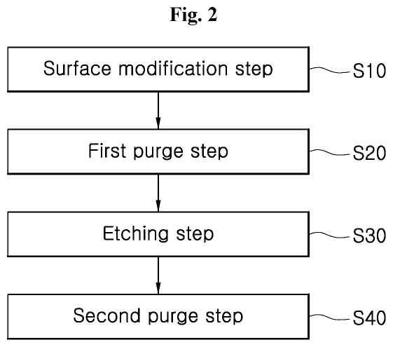

FIG. 2 is a flowchart illustrating a substrate processing method according to an embodiment of the present disclosure.

Referring to FIG. 2, the substrate processing method is for etching a thin film formed on a substrate at the atomic layer level, and may include: a surface modification step S10 of modifying a surface of the thin film by supplying a first gas including chlorine (Cl) to a processing space of a chamber in which the substrate is placed; a first purge step S20 of removing the first gas remaining in the processing space by supplying a purge gas to the processing space; an etching step S30 of etching the modified thin film by supplying a second gas including acetylacetone (Hacac) to the processing space; and a second purge step S40 of removing the second gas remaining in the processing space by supplying the purge gas to the processing space. The sequence of the surface modification step S10 to the second purge step S40 is defined as one cycle. This cycle may be repeated at least 1 time to etch the thin film formed on the substrate to a desired thickness.

The surface modification step S10 is a step of modifying the surface of the thin film by supplying the first gas including chlorine (Cl). The first gas including chlorine (Cl) may be supplied from a gas supply unit. The supplied first gas may be converted into a plasma state and supplied to the substrate. The first gas in the plasma state may undergo a chemical reaction with the thin film formed on the substrate, thereby modifying the surface layer of the thin film. The first gas according to the embodiment of the present disclosure is Cl₂ gas, but is not limited thereto. The first gas may be supplied to the processing space of the chamber for a predetermined period of time. In the surface modification step S10, a surface of a cobalt film formed on a silicon oxide film or silicon nitride film may be modified at the atomic layer or molecular layer level. For example, the surface layer of the cobalt film may react with a plasma of Cl₂ gas and be modified into a cobalt chloride (CoClₓ) film.

The first purge step S20 is a step of removing the first gas remaining in the processing space inside the chamber by supplying the purge gas from the gas supply unit. The purge gas may be supplied after the supply of the first gas is stopped, and may be supplied directly to the processing space inside the chamber without the use of plasma. Due to the supply of the purge gas, the first gas, which is supplied in the surface modification step S10 and remains in the processing space inside the chamber, and reaction by-products may be removed from the processing space. As the purge gas, an inert gas such as argon (Ar), helium (He), or nitrogen (N₂) may be used.

The etching step S30 is a step of etching the modified thin film by supplying the second gas including Hacac. The second gas including Hacac may be supplied from the gas supply unit to etch the modified thin film. The second gas according to the embodiment of the present disclosure may be a mixed gas of Hacac and nitrogen (N₂). The second gas may be supplied to the processing space of the chamber for a predetermined period of time. The Hacac may etch the surface layer of the modified thin film by reacting with the surface of the thin film modified in the surface modification step S10 while generating volatile etching by-products. According to the embodiment of the present disclosure, the cobalt chloride film modified in the surface modification step S10 may be etched at the atomic or molecular layer level by reacting with the Hacac while generating volatile cobalt chloride acetylacetone (Co(acac)ₓCl_{y}) and hydrochloric acid (HCl).

The second purge step S40 is a step of removing the second gas remaining in the processing space inside the chamber by supplying the purge gas from the gas supply unit. The purge gas may be supplied after the supply of the second gas is stopped, and may be supplied directly to the processing space inside the chamber without the use of plasma. Due to the supply of the purge gas, the second gas, which is supplied in the etching step S30 and remains in the processing space inside the chamber, and etching by-products may be removed from the processing space. As the purge gas, an inert gas such as argon (Ar), helium (He), or nitrogen (N₂) may be used.

The substrate processing method according to the embodiment of the present disclosure may be performed by heating the substrate. The substrate may be heated by a heating member of a substrate support unit supporting the substrate. Here, the temperature of the substrate may be in the range of 125° C. to 175° C.

As described above, in order to etch the thin film, that is, the cobalt film, formed on the substrate using the substrate processing method of the present disclosure at the atomic layer level, the cobalt film formed on the substrate may be modified with a plasma of Cl₂, which is the first gas, and the modified cobalt film may be etched with the second gas including Hacac at the atomic or molecular layer level. Since Hacac is about 10 times cheaper than conventionally used Hhfac, the manufacturing cost of devices can be lowered by using the substrate processing method.

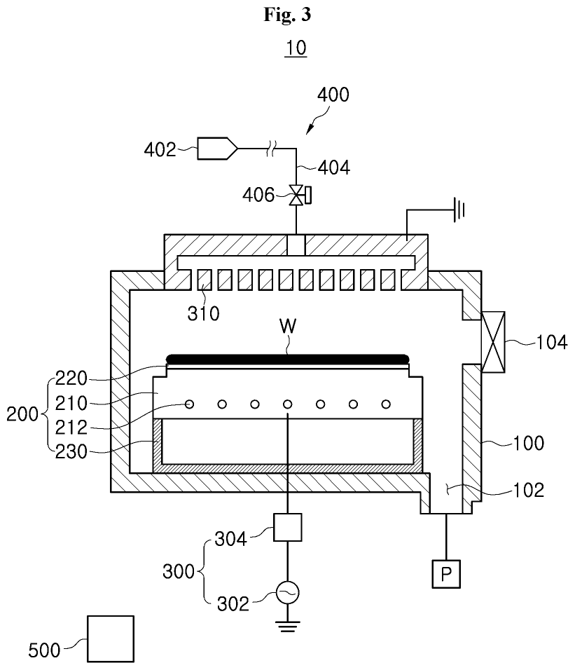

FIG. 3 is a view illustrating a substrate processing apparatus 10 according to an embodiment of the present disclosure.

Referring to FIG. 3, the substrate processing apparatus 10 according to the embodiment of the present disclosure may include a chamber 100, a substrate support unit 200, a plasma generation unit 300, a gas supply unit 400, and a control unit 500.

The chamber 100 has a processing space where a plasma process is performed. The chamber 100 may have an exhaust port 102 at a lower portion thereof. The exhaust port 102 may be connected to an exhaust line on which a pump P is mounted. The exhaust port 102 may discharge reaction by-products generated during a plasma process and gas remaining inside the chamber 100 to the outside of the chamber 100 through the exhaust line. In this case, the internal space of the chamber 100 may be depressurized to a predetermined pressure.

The chamber 100 may have an opening 104 on a side wall thereof. The opening 104 may function as a passage through which a substrate W enters and exits the chamber 100. The opening 104 may be configured to be opened and closed by a door assembly.

The substrate support unit 200 may include a support body 210 and an electrostatic chuck 220 disposed on the support body 210. The electrostatic chuck 220 may be configured to electrostatically adsorb the substrate W, and may include ceramic layers with an electrode interposed therebetween.

According to the embodiment of the present disclosure, a heating member 212 may be provided inside the support body 210. The heating member 212 may heat the substrate W to a preset temperature. For example, the heating member 212 may be a heating coil, but is not limited thereto.

A support member 230 may be provided under the support body 210 to support the support body 210 and the electrostatic chuck 220. The support member 230 may have a cylindrical shape with a predetermined height and may have a space therein.

The plasma generation unit 300 may generate a plasma in the processing space of the chamber 100. The plasma may be formed in an upper area of the substrate support unit 200 inside the chamber 100. According to the embodiment of the present disclosure, the plasma generation unit 300 may generate a plasma in the processing space inside the chamber 100 using a capacitively coupled plasma (CCP) source.

However, the present disclosure is not limited thereto. The plasma generation unit 300 may generate a plasma in the processing space inside the chamber 100 using another type of plasma source, such as an inductively coupled plasma (ICP) source or a microwave.

The plasma generation unit 300 may include a high-frequency power source 302 and a matcher 304. The high-frequency power source 302 may supply high-frequency power to either an upper electrode or a lower electrode to generate a potential difference between the upper electrode and the lower electrode. Here, the upper electrode may be a showerhead 310, and the lower electrode may be the substrate support unit 200. The high-frequency power source 302 may be connected to the lower electrode, and the upper electrode may be grounded.

The showerhead 310 may be formed to vertically face the electrostatic chuck 220 inside the chamber 100. The showerhead 310 may be provided with a plurality of gas spray holes to evenly spray gas into the chamber 100, and may have a larger diameter than the electrostatic chuck 220. Meanwhile, the showerhead 310 may be manufactured using a silicon material, and may also be manufactured using a metal material.

The gas supply unit 400 may supply a gas required for the process to the processing space of the chamber 100. The gas supply unit 400 may include a gas source 402, a gas supply line 404, and a gas spray nozzle. The gas supply line 404 may connect the gas source 402 and the gas spray nozzle to each other. A valve 406 may be installed in the gas supply line 404 to open and close a passage of the gas supply line 404 or to control the flow rate of fluid flowing through the passage.

FIG. 3 illustrates only one gas source 402 and one gas supply valve 406, but the present disclosure is not limited thereto. For example, a plurality of gas sources 402 may be provided to supply a plurality of gases to the chamber 100, and a plurality of gas supply valves may be provided to independently control the supply of each gas. The plurality of gases are gases used to modify the substrate W or to etch the modified substrate W, may include, for example, a first gas for modifying a surface of a thin film formed on the substrate W, a second gas for etching the modified thin film, and an inert gas for purging. The first gas is a gas including chlorine (Cl) and may be Cl₂, and the second gas may be a mixed gas of Hacac and nitrogen (N₂), but the present disclosure is not limited thereto.

The control unit 500 may comprehensively control the operation of the substrate processing apparatus 10 configured as described above. The control unit 500 is, for example, a computer and may include a central process unit (CPU), random access memory (RAM), read only memory (ROM), and auxiliary memory. The CPU may operate on the basis of programs or process conditions stored in the ROM or auxiliary memory and control the entire operation of the apparatus 10.

The control unit 500 according to the embodiment of the present disclosure may control so that the first gas is supplied to the processing space inside the chamber 100 and the first gas is converted into a plasma state by the plasma generation unit 300. In addition, the control unit 500 may control the heating member 212 of the substrate support unit 200 to maintain the temperature of the substrate W in the range of 125° C. to 175° C. during an etching process.

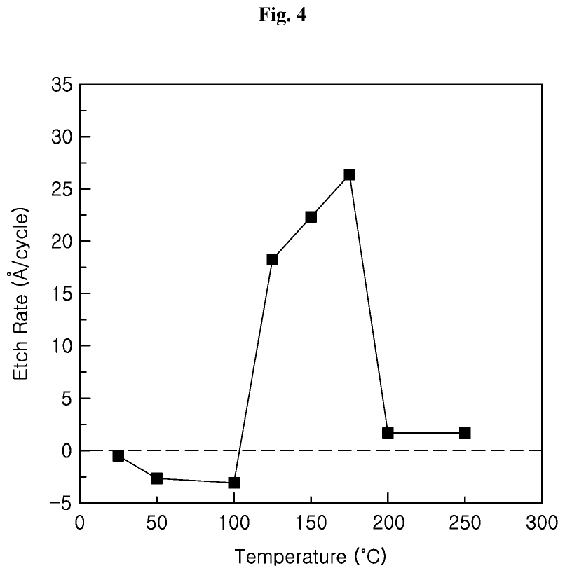

Next, experimental examples in which an atomic layer etching process was performed using the substrate processing apparatus illustrated in FIG. 3 will be described. FIGS. 4 to 6 are graphs illustrating experimental examples according to an embodiment of the present disclosure.

In the experimental examples according to the embodiment of the present disclosure, an etching process was performed on a silicon substrate including a silicon oxide film of about 200 nm formed thereon and a cobalt film of about 50 nm formed on the silicon oxide film.

FIG. 4 is a graph illustrating the etch rate according to the temperature of a substrate according to an embodiment of the present disclosure. To evaluate the etch rate of the cobalt film according to the temperature of the substrate, the etching amount per cycle according to temperature was measured while changing the temperature of the substrate from 25° C. to 250° C. under the conditions in Table 1 below. Here, the etching process was performed for 30 cycles for each temperature of the substrate.

TABLE 1

Process conditions

| | | | |
|---|---|---|---|
| Surface modification step | Pressure | 50 | mTorr |
| (S10) | Time | 20 | sec |
| First purge step | Time | 60 | sec |
| (S20) | | | |
| Etching step | Pressure | 200 | mTorr |
| (S30) | Time | 100 | sec |
| Second purge step | Time | 60 | sec |
| (S40) | | | |

Referring to FIG. 4, when the temperature of the substrate is 25° C. to 100° C., the cobalt film is not etched. In more detail, the cobalt film is modified into a cobalt chloride film by reacting with a first gas including chlorine (Cl), but due to the low temperature of the substrate, Hacac is adsorbed on the cobalt chloride film without reacting with the cobalt chloride film.

When the temperature of the substrate is 125° C., the etching amount of the cobalt film is about 17 A per cycle.

When the temperature of the substrate is 150° C., the etching amount of the cobalt film is about 22 A per cycle.

When the temperature of the substrate is 175° C., the etching amount of the cobalt film is about 26 A per cycle.

When the temperature of the substrate is 200° C. or 250° C., the etching amount of the cobalt film is about 1.5 A per cycle. This may be due to the fact that the cobalt film is modified to the cobalt chloride film through the reaction with the first gas including chlorine but the Hacac is decomposed due to the high temperature of the substrate. That is, since the amount of Hacac for etching the modified cobalt chloride film is not sufficient, the etching amount per cycle is significantly reduced.

From these experimental results, it can be found that it is most desirable to etch the cobalt film when the temperature of the substrate is in the range of 125° C. to 175° C. Therefore, when etching the cobalt film at 125° C. to 175° C., the controllability of the etching process can be improved, and the etching amount per cycle can be improved, thereby increasing the etch rate.

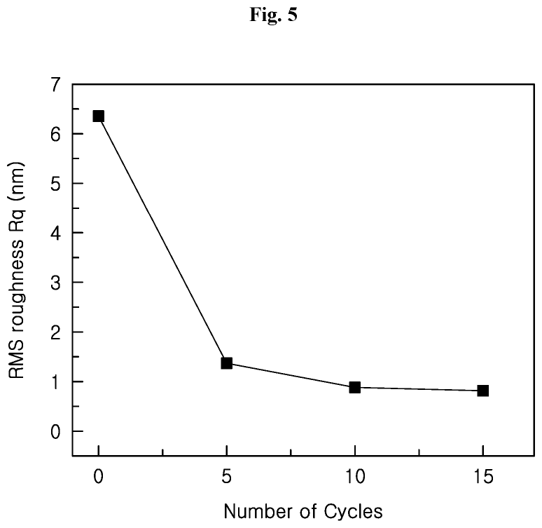

FIG. 5 is a graph illustrating the surface roughness of the etched cobalt film per cycle. The surface roughness of the etched cobalt film was measured under the conditions in Table 2 below.

TABLE 2

| | Process conditions | | | Temperature |
|---|---|---|---|---|
| Surface modification step | Pressure | 50 | mTorr | 125° C. |
| (S10) | Time | 5 | sec | |
| First purge step | Time | 60 | sec | |
| (S20) | | | | |
| Etching step | Pressure | 200 | mTorr | |
| (S30) | Time | 100 | sec | |
| Second purge step | Time | 60 | sec | |
| (S40) | | | | |

To evaluate the surface roughness of the cobalt film, the root mean square roughness was measured using an atomic force microscope (AFM).

Referring to FIG. 5, when the etching process is not performed on the substrate, the surface roughness of the cobalt film is about 6.5 nm.

When the etching process is performed for 5 cycles under the above conditions, the surface roughness of the etched cobalt film is about 1.5 nm.

When the etching process is performed for 10 cycles, the surface roughness of the etched cobalt film is about 1 nm.

When the etching process is performed for 20 cycles, the surface roughness of the etched cobalt film is about 0.8 nm.

That is, it can be found that in the case of the etched cobalt film, the surface roughness is reduced by about 6% per cycle. This indicates that the surface of the etched cobalt film is even.

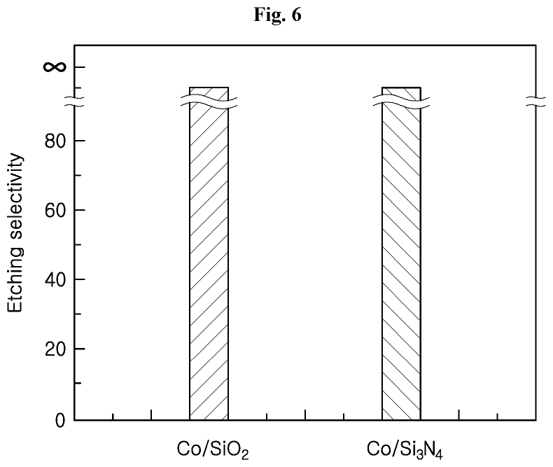

FIG. 6 is a graph illustrating the etching selectivity according to the type of substrate. According to the embodiment of the present disclosure, the substrate may include a silicon oxide film or a silicon nitride film, and a cobalt film may be formed on the silicon oxide film or silicon nitride film.

An etching process was performed on a silicon substrate including a silicon nitride film of about 200 nm formed thereon and a cobalt film of about 50 nm formed on the silicon nitride film.

To evaluate the etching selectivity of the cobalt film formed on the silicon oxide film and the etching selectivity of the cobalt film formed on the silicon nitride film, the etching process was performed for 15 cycles under the conditions in Table 2 above and then the etching selectivity according to the type of substrate was confirmed.

Referring to FIG. 6, in the case of the cobalt film formed on the silicon oxide film, the etching selectivity to the silicon oxide film is infinite. Also, in the case of the cobalt film formed on the silicon nitride film, the etching selectivity to the silicon nitride film is infinite. This indicates that the cobalt film is etched but the silicon oxide film and silicon nitride film are not etched, and it can be found that the cobalt film can be etched with a high etching selectivity to the silicon oxide film or silicon nitride film.

As can be seen from the above experimental results, the cobalt film formed on the silicon oxide film or silicon nitride film is etched by modifying the cobalt film with the first gas including chlorine (Cl) and etching the modified cobalt film with the second gas including Hacac, so it is possible to dramatically reduce the manufacturing cost of devices compared to the related art.

In addition, by using the first gas and the second gas, it is possible to reduce the surface roughness of the etched cobalt film, thereby reducing device defects caused by leakage current.

Moreover, by selectively etching the cobalt film to the silicon oxide film and silicon nitride film, it is possible to achieve excellent etching selectivity. Based on the above-described advantages, the present disclosure can be applied to various processes.

Although the exemplary embodiments of the present disclosure have been described for illustrative purposes, those skilled in the art will appreciate that various modifications, additions, and substitutions are possible, without departing from the scope and spirit of the present disclosure. Therefore, the exemplary embodiments of the present disclosure have not been described for limiting purposes, and the scope of the disclosure is not to be limited by the above embodiments. The scope of the present disclosure should be determined on the basis of the descriptions in the appended claims, and all equivalents thereof should belong to the scope of the present disclosure.

What is claimed is:

1. A substrate processing method for etching a thin film formed on a substrate at an atomic layer level, the substrate processing method comprising:
a surface modification step of modifying a surface of the thin film by supplying a first gas including chlorine (Cl) to a processing space of a chamber in which the substrate is placed;
a first purge step of removing the first gas remaining in the processing space by supplying a purge gas to the processing space;
an etching step of etching the modified thin film by supplying a second gas including acetylacetone (Hacac) to the processing space; and
a second purge step of removing the second gas remaining in the processing space by supplying the purge gas to the processing space.

2. The substrate processing method of claim 1, wherein a cycle including the surface modification step to the second purge step is repeated at least 1 time.

3. The substrate processing method of claim 1, wherein the thin film is a cobalt film.

4. The substrate processing method of claim 3, wherein the substrate includes at least one of a silicon oxide film and a silicon nitride film.

5. The substrate processing method of claim 4, wherein the substrate includes a stacked film in which the silicon oxide film and the silicon nitride film are alternately stacked,
wherein the cobalt film is formed in an opening formed through the stacked film.

6. The substrate processing method of claim 1, wherein the first gas is Cl₂, and the second gas is a mixed gas of the Hacac and nitrogen (N₂).

7. The substrate processing method of claim 1, wherein the surface modification step is performed in a state in which a plasma of the first gas is generated in the processing space.

8. The substrate processing method of claim 1, wherein the surface modification step to the second purge step are performed in a state in which the substrate is heated to a predetermined temperature.

9. The substrate processing method of claim 8, wherein the predetermined temperature is 125° C. to 175° C.

10. A substrate processing apparatus, comprising:
a chamber having a processing space therein;
a substrate support unit disposed in the processing space, configured to support a substrate, and including a heating member configured to heat the substrate;
a gas supply unit configured to supply a first gas including chlorine (Cl) and a second gas including acetylacetone (Hacac) to the processing space;
a plasma generation unit configured to convert the first and second gases supplied from the gas supply unit into a plasma state; and
a control unit configured to control the gas supply unit and the plasma generation unit,
wherein the control unit controls the gas supply unit and the plasma generation unit so that a plasma of the first gas is generated in the processing space to modify a thin film formed on the substrate and the second gas is supplied to the processing space to etch the modified thin film formed on the substrate.

11. The substrate processing apparatus of claim 10, wherein the thin film is a cobalt film.

12. The substrate processing apparatus of claim 11, wherein the cobalt film is formed on a silicon oxide or silicon nitride film.

13. The substrate processing apparatus of claim 10, wherein the first gas is Cl₂, and the second gas is a mixed gas of the Hacac and nitrogen (N₂).

14. The substrate processing apparatus of claim 10, wherein the control unit controls the heating member to maintain a temperature of the substrate at 125° C. to 175° C.

15. A substrate processing method for etching a thin film formed on a substrate for manufacturing 3D NAND devices at an atomic layer level, the substrate processing method comprising:
a surface modification step of modifying a surface of the thin film by supplying a first gas including chlorine (Cl) to a processing space of a chamber;
a first purge step of removing the first gas remaining in the processing space by supplying a purge gas to the processing space;
an etching step of etching the modified thin film by supplying a second gas including acetylacetone (Hacac) to the processing space; and
a second purge step of removing the second gas remaining in the processing space by supplying the purge gas to the processing space,
wherein the first gas is Cl₂,
the second gas is a mixed gas of the Hacac and nitrogen (N₂), and
one cycle defined from the surface modification step to the second purge step is repeated at least 1 time and is performed while maintaining the substrate at a temperature of 125° C. to 175° C.

16. The substrate processing method of claim 15, wherein the thin film is a cobalt film.

17. The substrate processing method of claim 16, wherein the substrate includes at least one of a silicon oxide film and a silicon nitride film.

18. The substrate processing method of claim 17, wherein the substrate includes a stacked film in which the silicon oxide film and the silicon nitride film are alternately stacked vertically, wherein the cobalt film is formed in an opening formed through the stacked film.

19. The substrate processing method of claim 17, wherein the substrate includes:
a stacked film in which the silicon oxide film and the silicon nitride film are alternately stacked vertically;
a slit-shaped first opening formed by etching the stacked film vertically; and
a plurality of second openings formed to extend horizontally from the slit-shaped first opening by selectively etching the silicon nitride film exposed in the slit-shaped first opening,
wherein the cobalt film is formed on surfaces of the slit-shaped first opening and the second openings.

20. The substrate processing method of claim 19, wherein a tunneling oxide is formed along the surfaces of the slit-shaped first opening and the second openings,
a nitride film trap is formed on the tunneling oxide,
a gate insulating film is formed on the nitride film trap,
a barrier layer is formed on the gate insulating film, and
the cobalt film is formed on the barrier layer.
